(19) United States
(12) Patent Application Publication
(10) Pub. No.: US 2012/0138590 A1
(43) Pub. Date: Jun. 7, 2012

(54) LIGHTING SYSTEM FOR USE WITH A COOKTOP APPLIANCE AND METHOD FOR ASSEMBLING THE SAME

(76) Inventors: Daniel V. BROSNAN, Louisville, KY (US); Brian Schork, Louisville, KY (US); Brvan Beckley, Louisville, KY (US); Mariano Filippa, Auburndale, MA (US); Ryan Turner, Trenton, IL (US); Timothy Shaffer, La Grange, KY (US)

(21) Appl. No.: 12/960,483

(22) Filed: Dec. 4, 2010

(51) Int. Cl. H05B 1/00; F25D 27/00; H05K 13/00

(52) U.S. Cl. 219/220; 29/592.1; 362/92

(57) ABSTRACT

A lighting system for a cooktop appliance having a plate and a burner assembly positioned beneath the plate. The lighting system includes at least one light source positioned adjacent a light entry portal of the plate. The at least one light source is configured to direct light through the plate via the light entry portal and emit the light from a top surface of the plate adjacent the burner assembly. A controller is communicatively coupled to the burner assembly and the at least one light source. The controller is configured to activate the at least one light source when at least one of the burner assembly is activated and a utensil on the burner assembly is heated.

### BACKGROUND OF THE INVENTION

The embodiments described herein relate generally to a lighting system for use with a cooktop appliance and, more particularly, to a lighting system for use with an induction cooktop appliance.

At least some known cooktop appliances generate a magnetic field that induces a current within a ferrous cooking utensil, such as a pot or pan. When using such a cooktop appliance, a user positions the ferrous cooking utensil adjacent a magnetic coil and activates the magnetic coil to generate the magnetic field. The current induced in the cooking utensil heats the cooking utensil and the contents of the cooking utensil. A top surface of the cooktop appliance remains substantially at room temperature, unless conductively heated by the utensil on the top surface. Further, and unlike a radiant or gas cooktop, an activated burner assembly does not emit a visual signal to the user that the burner assembly is activated. As such, the user may erroneously believe that a burner assembly is inactive, when the cooking utensil on the burner assembly may be heated.

One known inductive cooktop appliance includes light-emitting diodes (LEDs) arranged in a closed loop. A current induced in the closed loop by the existing magnetic field illuminates the LEDs. However, the indirect powering of the LEDs does not provide direct control of the LEDs to provide the user with any indications other than “off” or “on.” As such, when the burner is off and the pan is still heated, the user sees the same visual indication as if the pan is cool.

### BRIEF SUMMARY OF THE INVENTION

In one aspect, a lighting system for use with a cooktop appliance is provided. The cooktop appliance includes a plate and a burner assembly positioned beneath the plate. The lighting system includes at least one light source positioned adjacent a light entry portal of the plate. The at least one light source is configured to direct light through the plate via the light entry portal and emit the light from a top surface of the plate adjacent the burner assembly. A controller is communicatively coupled to the burner assembly and the at least one light source. The controller is configured to activate the at least one light source when at least one of the burner assembly is activated and a utensil on the burner assembly is heated.

In another aspect, a cooktop appliance is provided. The cooktop appliance includes a plate having a light entry portal, and a burner assembly positioned beneath the plate. The burner assembly includes an induction coil. The cooktop appliance further includes a lighting system including at least one light source positioned adjacent the light entry portal. The at least one light source is configured to direct light through the plate via the light entry portal and emit the light from a top surface of the plate adjacent the burner assembly.

In yet another aspect, a method for assembling a cooktop appliance is provided. The cooktop appliance includes a burner assembly having an induction coil. The method includes positioning a plate above the burner assembly. The plate includes a first area, which is substantially transparent, defined on a top surface of the plate. The first area is aligned with the burner assembly. The method further includes coupling at least one light source adjacent a light entry portal of the plate. The at least one light source is configured to direct light through the plate via the light entry portal and emit the light from the top surface of the plate at the first area. A controller is communicatively coupled to the burner assembly and the at least one light source.

### BRIEF DESCRIPTION OF THE DRAWINGS

FIGS. 1-9 show exemplary embodiments of the systems and method described herein.

FIG. 1 is a perspective view of an exemplary cooktop appliance.

FIG. 2 is a schematic cross-sectional view of the cooktop appliance shown in FIG. 1.

FIG. 3 is a schematic view of a burner assembly and a lighting system that may be used with the cooktop appliance shown in FIGS. 1 and 2.

FIG. 4 is a schematic view of a plurality of burner assemblies and a lighting system that may be used with the cooktop appliance shown in FIGS. 1 and 2.

FIG. 5 is a schematic view of an alternative arrangement of the plurality of burner assemblies shown in FIG. 4.

FIG. 6 is a schematic view of an alternative lighting system that may be used with the cooktop appliance shown in FIGS. 1 and 2.

FIG. 7 is an illustration of a first example of a lighting pattern that can be generated using the lighting system shown in FIG. 6.

FIG. 8 is an illustration of a second example of a lighting pattern that can be generated using the lighting system shown in FIG. 6.

FIG. 9 is a flowchart of an exemplary method for assembling the cooktop appliance shown in FIGS. 1-8.

### DETAILED DESCRIPTION OF THE INVENTION

The embodiments described herein provide an integrated lighting system for induction coils that illuminates when an induction coil is active and/or operating in any other relevant state. The lighting system described herein can give an appearance to an induction coil in a cooktop appliance that is similar to an appearance of a radiant electric cook-top burner, a gas burner, and/or any other suitable heated/energized element. Various colors and/or intensities of light are used to convey various parameters to the user and to enhance aesthetics of the induction coils.

In particular embodiments described herein, the lighting system includes light-emitting diodes and a light-guiding plate; glow wires; glowing paint and/or polymer; glowing liquid, gas, and/or solid; and/or controllable privacy glass. Further, the lighting system can be scaled up or down according to a size of a cooking utensil detected over a burner assembly and/or a size of a burner assembly. All lighting systems described herein can be directly powered by a power source and/or powered by a current induced by a magnetic field. In the figures, red light is indicated by a square dotted line and blue light is indicated by a dashed line. Although red light and blue light are described herein, it should be understood that any colors of light and/or any number of different colors of light can be used with the lighting system described herein.

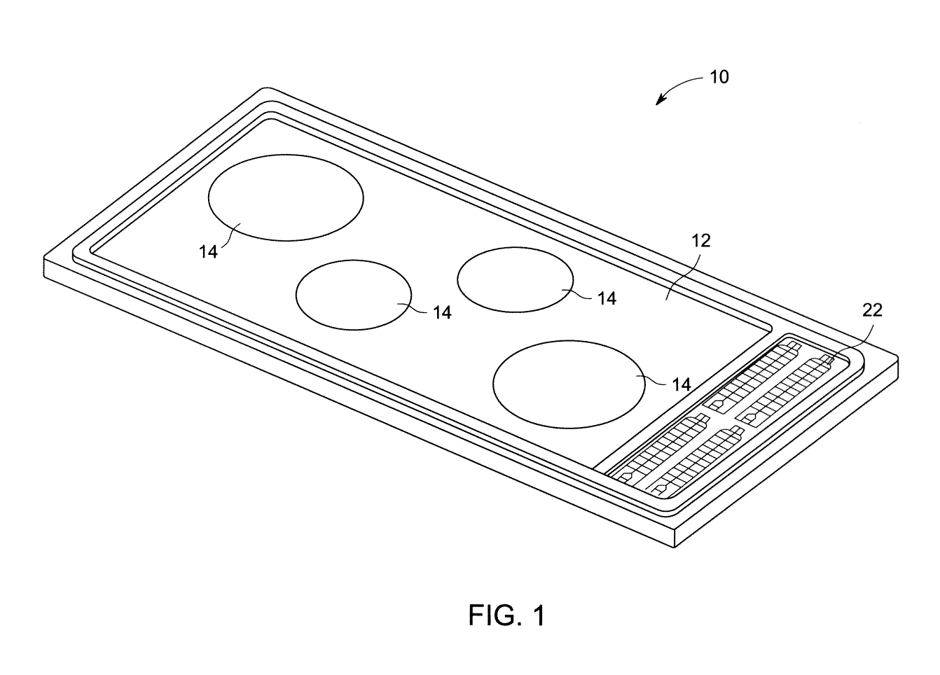

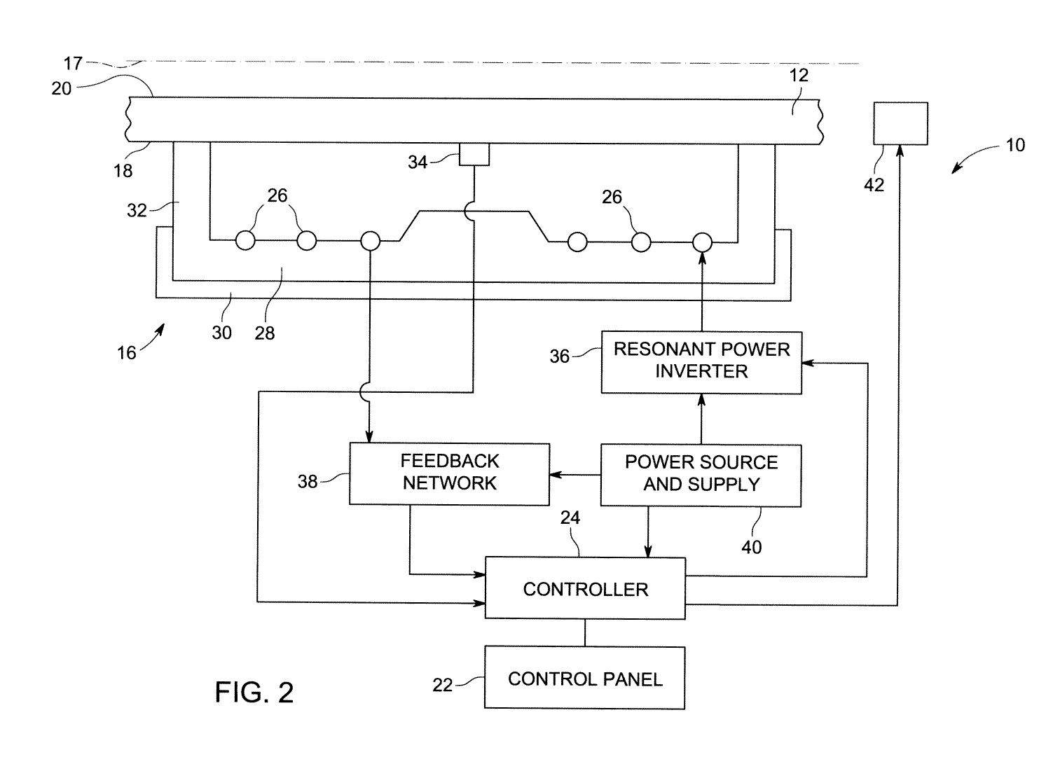

FIG. 1 is a perspective view of an exemplary cooktop appliance 10. FIG. 2 is a schematic cross-sectional view of cooktop appliance 10. Cooktop appliance 10 includes a plate 12 that acts as a cooking surface. Plate 12 can be formed from glass, ceramic, vitroceramic glass (transparent or opaque), quartz, fused silica, borosilicate, sodalime glass, plastic, polycarbonate, and/or any other suitable light transmitting material.

In an alternative embodiment, plate 12 is positioned below a cooking surface plate 17 of cooktop appliance 10 and does not act as the cooking surface. For example, plate 12 can be positioned between a burner assembly 16 and a cooking surface plate 17 (shown in phantom in FIG. 2). In such an embodiment, cooking surface plate 17 is transparent and/or opaque to light and/or patterned in any suitable manner than enables cooktop appliance 10 to function as described herein. In a particular embodiment when cooking surface plate 17 is included in cooktop appliance 10, cooking surface plate 17 is configured similarly to plate 12, and plate 12 transmits light to cooking surface plate 17. Further, it should be understood that cooktop appliance 10 can be any type of cooktop appliance including, but not limited to, a range having an oven and a cooktop provided thereon or a built-in cooktop unit without an oven.

In the exemplary embodiment, patterns 14 formed on the cooking surface of plate 12 identify positions of each burner assembly 16 located directly underneath plate 12 at each pattern 14. Patterns 14 can have any suitable shape, such as, circular, oval, and/or polygonal. When cooking appliance 10 includes cooking surface plate 17, patterns 14 are defined on plate 12 and/or cooking surface plate 17 above each burner assembly 16. In the exemplary embodiment, a bottom surface 18 and/or a top surface 20 of plate 12 is angle-cut, dimpled, etched, and/or patterned for strength, aesthetics, light diffusion, and/or for any other suitable reason. Appliance 10 also includes a control panel 22 that includes input devices, such as knobs and/or touch pads, that allow a user of appliance 10 to control temperatures of burner assemblies 16 individually or in combination via a controller 24.

Referring to FIG. 2, each burner assembly 16 is located beneath plate 12. Burner assembly 16 includes a controllable induction coil 26, such as an inductively wound litz wire element that produces a surrounding magnetic field when excited by a high frequency current, such as a current having a frequency above a human's hearing range of about 15 Hertz (Hz) to about 20 kilo-Hertz (kHz). For example, the current has a frequency between about 20 kHz and about 50 kHz. In one embodiment, the current has a frequency between about 20 kHz and about 25 kHz. In another embodiment, the current has a frequency between about 30 kHz and 35 kHz to simmer contents within a utensil over burner assembly 16.

It should be noted that any suitable type of energy source, such as an RF generator, could be used in place of the resistance element and/or induction coil 26. In the exemplary embodiment, induction coil 26 is arranged in an effective heating pattern, such as a concentric coil, and is secured to a base of an insulating liner 28 supported in a support pan 30. Insulating liner 28 includes an annular, upwardly extending portion 32 that serves as an insulating spacer between induction coil 26 and plate 12. Support pan 30 is supported by conventional support means (not shown) for locating burner assembly 16 at a position relative to plate 12. Each burner assembly 16 includes at least one sensing device 34 to detect one or more characteristics relating to appliance 10, such as a temperature of plate 12; a presence or an absence of a utensil on plate 12; a temperature, a size, and/or a type of utensil on plate 12; and/or the properties or state of the utensil contents. Sensing device 34 can be discretely located or distributed across burner assembly 16. In one embodiment, leads from sensing device 34 extend from burner assembly 16 to controller 24.

Controller 24 is configured to control a power level of induction coil 26 in response to the user selected settings entered via control panel 22 and/or to control any other suitable operations of appliance 10. In the exemplary embodiment, controller 24 is communicatively coupled to induction coil 26 via resonant power inverter 36 and a feedback network 38. A power supply and source 40 is also communicatively coupled to induction coil 26 via resonant power inverter 36. Further, power supply and source 40 is communicatively coupled to controller 24 and feedback network 38. As used herein, “communicatively coupled,” or variations thereof, refers to a link, such as a conductor, a wire, and/or a data link, between two or more components of appliance 10 that enables signals, electric currents, voltages, and/or commands to be communicated between the two or more components. The link is configured to enable one component to control an operation of another component of appliance 10 using the communicated signals, electric currents, voltages, and/or commands.

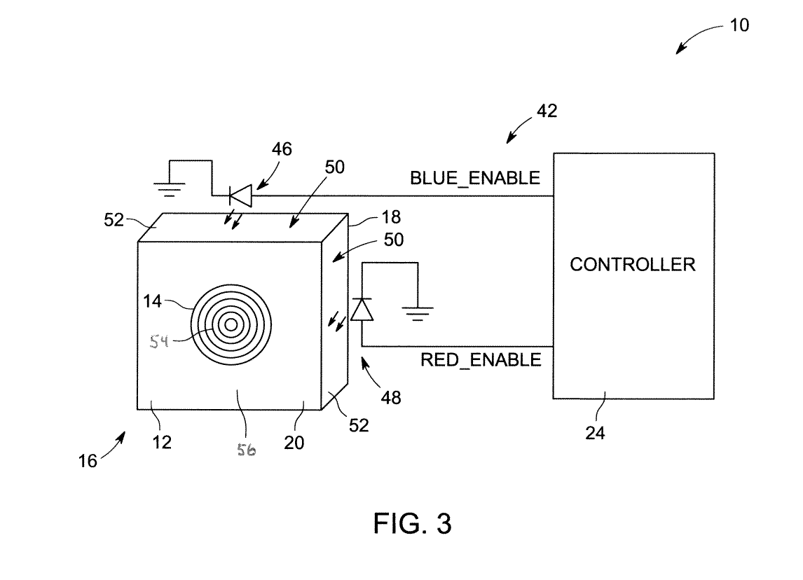

Appliance 10 further includes a lighting system 42 configured to illuminate each burner assembly 16 to provide the user with a visual indication of a status of burner assemblies 16. For example, lighting system 42 illuminates an active burner assembly 16 and maintains a darkened state of a non-active burner assembly 16. Lighting system 42 can additionally or alternatively use colors and/or intensities to indicate a temperature of each burner assembly 16, such as not illuminating a non-active burner assembly 16, illuminating a cool burner assembly 16 with blue light, and/or illuminating a hot burner assembly 16 with red light. Other colors and/or color intensities can be used to indicate ranges of temperatures between cool and hot. In the exemplary embodiment, controller 24 controls lighting system 42 to provide visual indications of a state of a burner assembly 16 to the user. Additional details of lighting system 42 and how it is made and/or operated are provided below with respect to FIGS. 3-8.

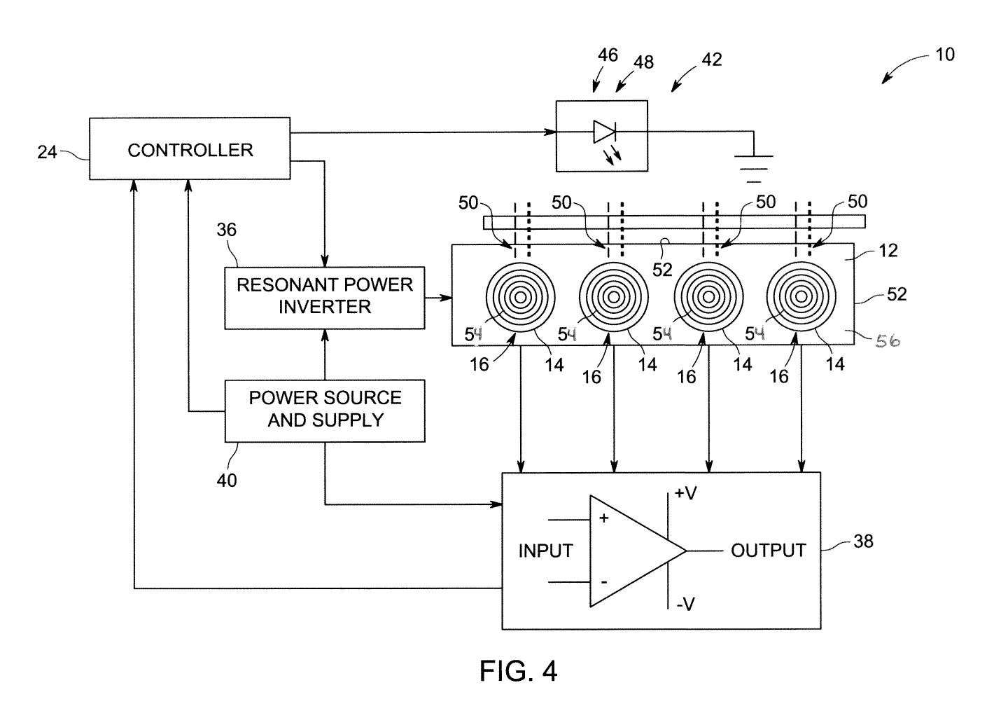

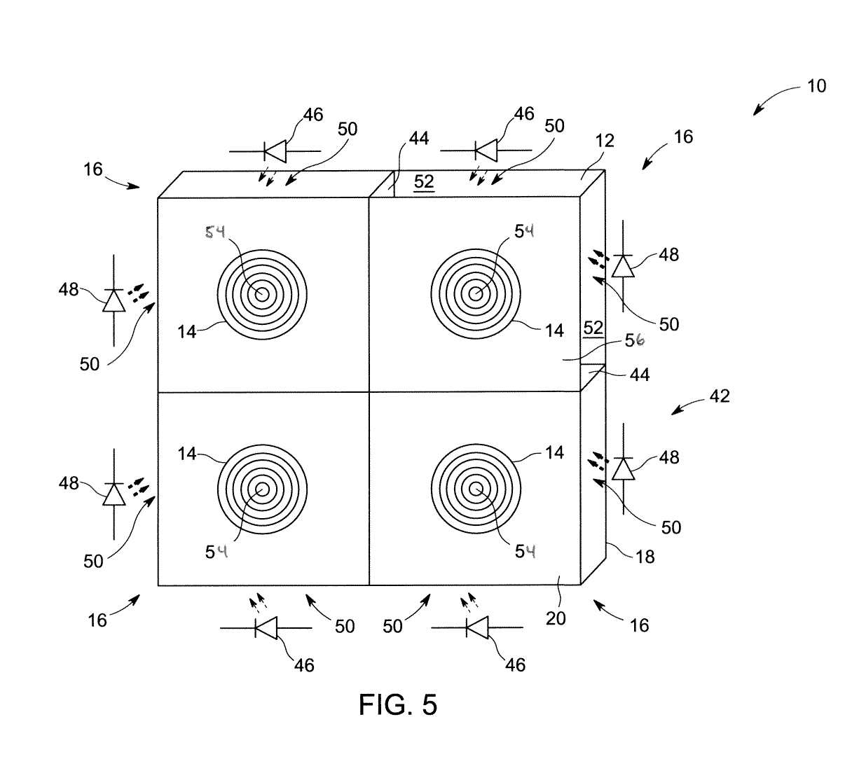

FIG. 3 is a schematic view of burner assembly 16 and lighting system 42. FIG. 4 is a schematic view of a plurality of burner assemblies 16 and lighting system 42. Although burner assemblies 16 are shown as being substantially linearly arranged in FIG. 4, burner assemblies 16 can be arranged in a grid as shown in FIG. 5. When burner assemblies 16 are arranged in a grid, partitions 44 can be positioned between adjacent burner assemblies 16 to prevent light emitted at a first burner assembly 16 from being emitted at a second burner assembly 16. Alternatively, burner assemblies 16 are arranged in any suitable configuration. Referring to FIGS. 3 and 4, in the exemplary embodiment, lighting system 42 includes at least one light source and, namely, a first light source 46 and a second light source 48. Each light source 46 and 48 emits a different color light. In the exemplary embodiment, first light source 46 emits blue light and second light source 48 emits red light. Alternatively, a single multi-color light source and/or more than two different color light sources can be used in lighting system 42. In the exemplary embodiment, each light source 46 and 48 is a light-emitting diode (LED), however, it should be understood that light source 46 and/or light source 48 can be any suitable light source than enables lighting system 42 to function as described herein. In the exemplary embodiment, each light source 46 and 48 is communicatively coupled to controller 24. Controller 24 is configured to control light sources 46 and/or 48 as described herein.

In alternative embodiments, lighting system 42 includes glow wires (not shown) wrapped in an arrangement around an induction coil within burner assembly 16. The glow wires can be directly powered by a power source (not shown) and/or powered through induction. In another alternative embodiment, lighting system 42 includes a chemical and/or material solid, liquid, and/or gas that glows in the presence of heat, an electrical current, and/or a magnetic field. Additionally, lighting system 42 can include privacy glass having a controllable dimness level. When privacy glass is used with lighting system 42, light can be emitted upward through the privacy glass, and the dimness level of the privacy glass controls an amount of light transmitted through the privacy glass to provide a visual indication of a state of burner assembly 16 to the user.

In the exemplary embodiment, plate 12 includes at least one substantially transparent light entry portal 50 along a side edge 52 of plate 12. In a particular embodiment, plate 12 includes a plurality of light entry portals 50 and each light source 46 and 48 is positioned adjacent a respective light entry portal 50. In the exemplary embodiment, each light entry portal 50 is defined at a surface of plate 12 that is cut, polished, and/or coated to facilitate allowing an optimum amount of light to enter plate 12. The remainder of side edge 52 (the portion of side edge 52 not including light entry portal 50) is configured to reflect light into plate 12 and/or to absorb light. For example, the remainder of side edge 52 is partitioned using, for example, paint, plastic, and/or angle cutting. When angle cutting is used, an angle is selected such that light is unable to be transmitted through the remainder of side edge 52. In the exemplary embodiment, side edges 52 extend between top surface 20 and bottom surface 18 of plate 12. Light sources 46 and 48 are positioned to direct light through plate 12 via light entry portal 50. As such, plate 12 acts as a light guide for the light emitted from light sources 46 and/or 48.

Top surface 20 includes at least one first area 54, which is substantially transparent, and at least one second area 56, which is substantially opaque. Second area 56 is configured to prevent light from being transmitted from plate 12 through top surface 20, and first area 54 is configured to direct light from plate 12 through top surface 20. In the exemplary embodiment, first areas 56 are defined at or within each pattern 14 on plate 12 such that light can be transmitted through plate 12 at each burner assembly 16. In one embodiment, each first area 54 includes a pattern, etching, cuts, and/or any other suitable light directing components that enable light to be directed from light source 46 and/or 48 through top surface 20 of plate 12 and upwards beyond a cooking surface of cooktop appliance 10. The light directing components can be within plate 12 at first area 54, below plate 12, and/or on top surface 20 at first area 54. When cooking surface plate 17 is used, cooking surface plate 17 and/or plate 12 include light directing components and/or are associated with light directing components. In the exemplary embodiment, a remainder of top surface 20, or a portion of top surface 20 surrounding first area(s) 56, is second area 56. Second area 56 can be formed using a coating on top surface 20 and/or any other suitable technique for rendering top surface 20 substantially opaque to prevent transmission of light from plate 12 to the user, while reflecting light back into plate 12. In the exemplary embodiment, first area 54 and second area 56 are defined to emit the light from top surface 20 of plate 12 adjacent burner assembly 16.

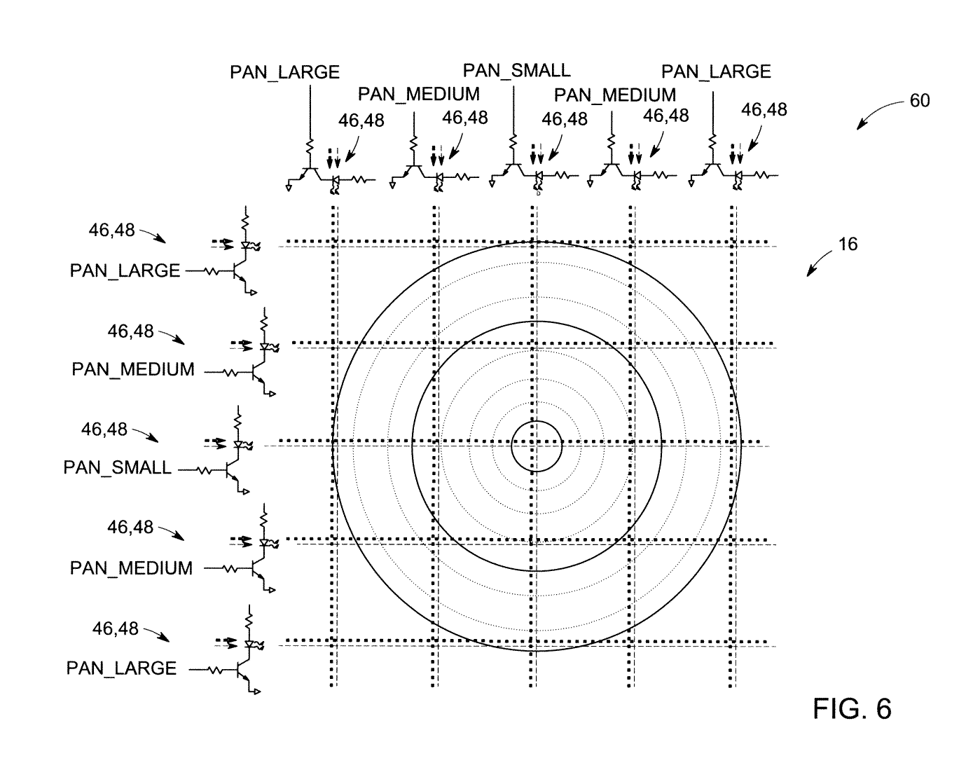

When cooktop appliance 10 includes a plurality of burner assemblies 16 as shown in FIGS. 4 and 5, plate 12 includes a plurality of first areas 56 each defined over a respective burner assembly 16, and at least one light source 46 and/or 48 is positioned to emit light from a respective first area 54. For example, when two light sources 46 and 48 are used, a pair of light sources 46 and 48 is positioned to emit light from each first area 54. More specifically, at least one light source 46 and/or 48 is coupled adjacent each burner assembly 16, and, in one embodiment, a pair of light sources 46 and 48 is associated with each burner assembly 16 in cooktop appliance 10. Controller 24 individually controls each pair of light sources 46 and 48 to indicate at least a status of each burner assembly 16. Alternatively, as shown in FIG. 6, at least one burner assembly 16 includes a plurality of pairs of light sources 46 and 48.

Referring again to FIGS. 3 and 4, in the exemplary embodiment, controller 24 is communicatively coupled to burner assembly 16 and lighting system 42 and, in particular, light sources 46 and 48. Controller 24 is configured to automatically activate at least one light source 46 and/or 48 when burner assembly 16 is activated. As such, controller 24 indicates an “on” status of burner assembly 16 by activating light sources 46 and/or 48. Alternatively, or additionally, as operating states of burner assembly 16 change, controller 24 changes a color of the light emitted at first area 54 accordingly. For example, when burner assembly 16 operates in a warming-up state, controller 24 activates light source 46 to emit blue light from first area 54 associated with burner assembly 16. When burner assembly 16 finishes warming-up and is operating in a cooking state, controller 24 activates light source 48 to emit red light from first area 54 associated with burner assembly 16. In such an embodiment, controller 24 can control light sources 46 and/or 48 to gradually change the color of the light emitted from first area 54 over a spectrum of colors.

In another example, when burner assembly 16 has been activated, but no utensil is detected on burner assembly 16, lighting system 42 generates a first ring of light about the activated burner assembly 16. In one embodiment, the first ring of light is a blue ring of light. When burner assembly 16 has been activated and the utensil is detected on burner assembly 16, lighting system 42 generates a second ring of light having a size proportional to a size and/or a position of the utensil. In one embodiment, the second ring of light has a color that is different than a color of the first ring of light, such as a red ring of light. As described herein, “blue light” is produced by electromagnetic waves having a wavelength between about 450 nanometers (nm) and about 500 nm, and “red light” is produced by electromagnetic waves having a wavelength between about 635 nm and about 700 nm. It should be understood that lighting system 42 can emit light having any suitable wavelength within the visible spectrum, such as a wavelength between about 380 nm and about 750 nm.

When burner assembly 16 has been activated and utensil is detected on burner assembly 16, the second ring of light can have an intensity (solid, pulsing, and/or modulating) proportional to a power level setting and/or feedback temperature of burner assembly 16. The first and/or second rings of light can be defined using light directing surfaces on or within plate 12 and/or using a configuration of light sources 46 and/or 48. Additionally, a pulsing, patterned, and/or modulating illumination sequence can be generated about burner assembly 16 by controller 24. To generate rings of light having different sizes, a lighting system 60 as shown in FIG. 6 can be used. Lighting system 60 includes components similar to lighting system 42 and similar components are labeled similarly in FIGS. 3-8. Lighting system 60 includes a plurality of pairs of light sources 46 and 48 positioned about burner assembly 16 to enable alteration of a size of an illuminated area of plate 12. Pairs of light sources 46 and 48 form a grid arrangement corresponding to different size utensils that can be positioned over burner assembly 16.

In another example, when burner assembly 16 is operating in a cooking state with a sufficiently sized cooking utensil (i.e. a cooking pot) thereon, controller 24 continuously activates light sources 46 and/or 48. When burner assembly 16 is operating in a cooking state with an insufficiently sized cooking utensil (i.e. a spoon and/or no utensil) thereon, controller 24 periodically activates light sources 46 and/or 48 to indicate to the user that the utensil is not of a sufficient size. In yet another example, controller 24 controls lighting system 42 to provide pulsating blue light when burner assembly 16 is on but no cooking utensil is detected, a pulsating red light when burner assembly 16 is on and the cooking utensil is detected, and a pulsating color spectrum when burner assembly 16 is heating the cooking utensil at full power. It should be understood that the above examples are not limiting and controller 24 can control lighting system 42 based on any suitable operations of burner assembly 16 and/or cooktop appliance 10.

In the exemplary embodiment, controller 24 activates lighting system 42 based on different types of signals to generate different illumination schemes, as described herein. The types of signals include system on/off signals, temperature setting signals, temperature feedback signals, pan sensing signals, resonant detection signals, efficiency measurement signals, and/or any other suitable signals. In the exemplary embodiment, signals are transmitted from sensing device 34 to controller 24, and controller 24 controls lighting system 42 based on the signals from sensing device 34.

The system on/off signals can be used as a master signal for determining whether or not to activate light sources 46 and/or 48 associated with a burner assembly 16. For example, illumination of burner assembly 16 is not possible when an “off” signal is generated for burner assembly 16. An exception is when plate 12 and/or utensil over burner assembly 16 is still hot after burner assembly 16 has been de-activated. The pan sensing signals indicate a “size” of burner assembly 16 to be illuminated. As discussed above with respect to lighting system 60, although the actual size of burner assembly 16 does not vary, the size of an illuminated area above burner assembly 16 can be varied based on a size of the utensil positioned over burner assembly 16. For example, small, medium, or large pans are illuminated accordingly using the grid arrangement of lighting system 60 shown, in FIG. 6. The temperature setting/feedback signals indicate an amount of heat energy being transferred by, or currently present in, the utensil. For example, sensing device 34 indirectly measures the heat energy of the utensil at the cooking surface. Controller 24 can vary an intensity of illumination by, for example, dimming or brightening the illumination, based on the temperature setting/feedback signals. In one example, controller 24 pulse width modulates (PWM) light sources 46 and/or 48 to generate a dim to bright (or modulating) illumination as the utensil heats to a desired temperature setting or level.

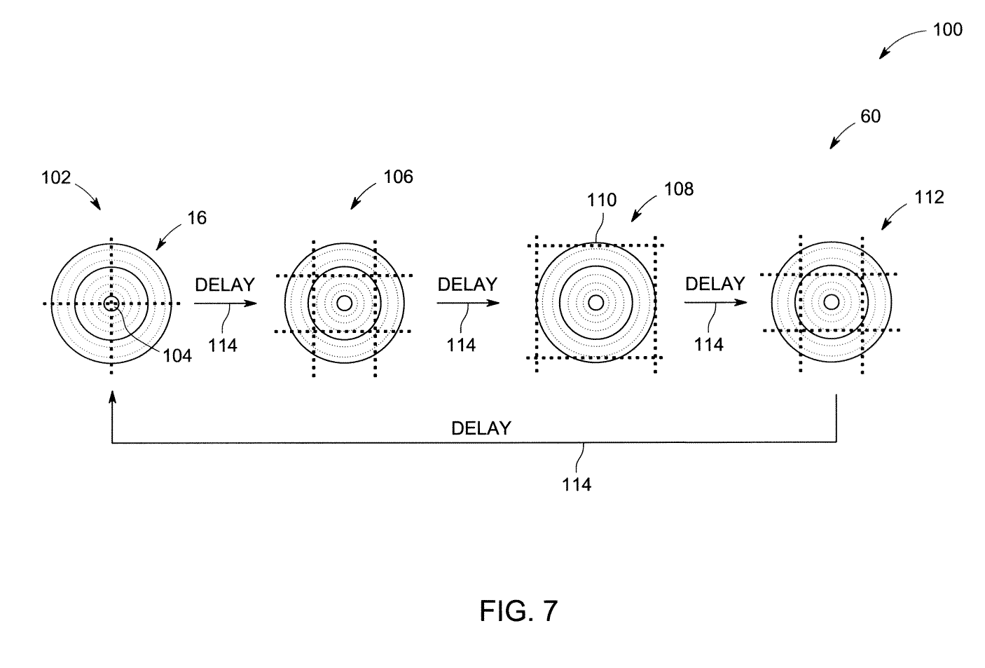

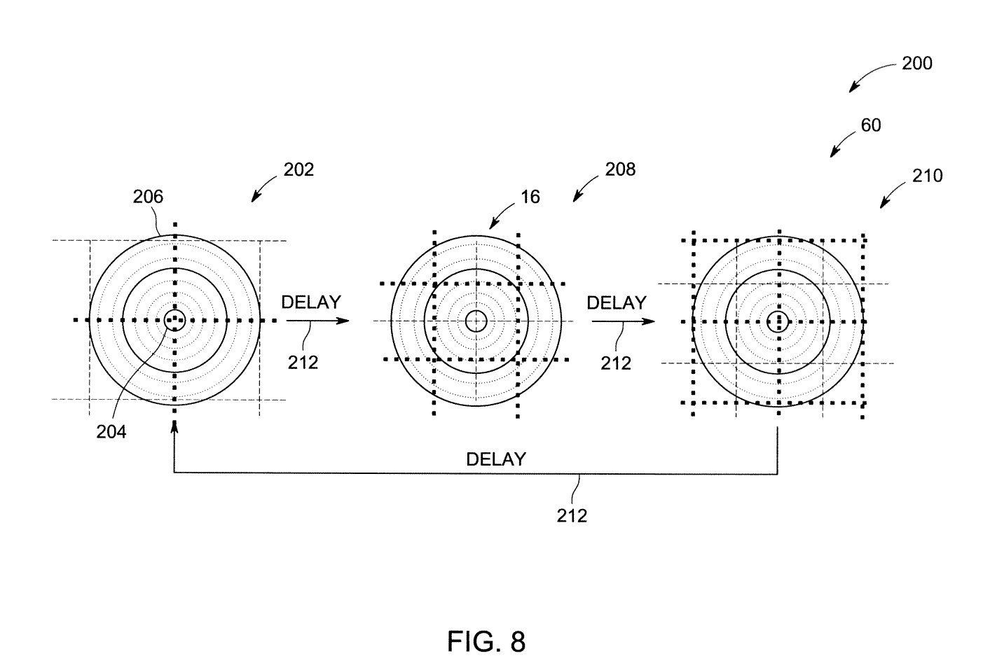

FIG. 7 illustrates a first example of a lighting pattern 100 using lighting system 60, and FIG. 8 illustrates a second example of a lighting pattern 200 using lighting system 60. The “delays” shown in FIGS. 7 and 8 indicate time delays. First and second example lighting patterns 100 and 200 can be automatically achieved by controller 24 based on the on/off signals, temperature setting signals, temperature feedback signals, pan sensing signals, resonant detection signals, efficiency measurement signals, and/or any other suitable signals from sensing device 34 and/or can be generated using predetermined lighting programs stored within controller 24. As used herein, the term “predetermined lighting program(s)” refers to computer software, firmware, hardware, computer readable instructions, and/or any other suitable instructions that direct lighting system 60 to activate and/or deactivate light sources 46 and/or 48 to generate a lighting pattern.

Referring to FIG. 7, lighting pattern 100 uses one color of light, for example, red light, to produce a “rippling” effect. More specifically, in a first stage 102, the light is most intense in a center 104 of burner assembly 16, and moves outwardly at a second stage 106. Second stage 106 continues to a third stage 108 in which the light is most intense at an outer edge 110 of burner assembly 16. A fourth stage 112 then begins in which the light returns to being most intense at center 104. Controller 24 (shown in FIG. 3) is programmed to perform a delay 114 between each stage 102, 106, 108, and 112. Delay 114 can have any suitable time duration. Further, although in the exemplary embodiment, each delay 114 has the same duration, any delay can have a duration different than any other delay. In the exemplary embodiment, delay 114 is reduced as temperature of the utensil on burner assembly 16 increases. As such, lighting system 42 (shown in FIG. 3) “ripples” faster as the temperature increases.

Referring to FIG. 8, lighting pattern 200 uses at least two colors of light, for example, red light and blue light, to produce a “color-mixing” effect. More specifically, in a first stage 202, a first color light is most intense in a center 204 of burner assembly 16 and a second color light is most intense at an outer edge 206 of burner assembly 16. During a second stage 208, the first color light moves outwardly toward outer edge 206 and the second color light is most intense at center 204. At a third stage 210, the first color light and second color light are substantially even mixed across burner assembly 16. Controller 24 (shown in FIG. 3) is programmed to perform a delay 212 between each stage 202, 208, and 210. Delay 212 can have any suitable time duration. Further, although in the exemplary embodiment, each delay 212 has the same duration, any delay can have a duration different than any other delay. In the exemplary embodiment, delay 212 is based on a temperature of the utensil on burner assembly 16 such that an overall color of light emitted from lighting system 42 (shown in FIG. 3) changes as the temperature increases. Alternatively, delays 212 can be selected to produce a two-color “rippling” effect that speeds up as temperature increases.

In addition, or alternatively to, the above-described automatic control of light sources 46 and/or 48, a user may input instructions into control panel 22 that causes lighting system 42 and/or 60 to display one or more user-selected lighting colors and/or patterns. The input instructions are stored in a memory of controller 24. Based on the input instructions, lighting system 42 emits the selected color and/or pattern of light from plate 12 using light sources 46 and/or 48. For example, when light source 46 and/or 48 is a multi-color LED and the user selects green light, controller 24 provides indications, such as a continuous lighting, pulsing lighting, and/or flashing lighting, by emitting green light from first area 54. The user can also select to turn off lighting system 42, and lighting system 42 will not provide lighting indications to the user; however, controller 24 may provided other indications to user that a utensil over burner assembly 16 may be hot. It should be understood that lighting system 42 can be scaled up or down to account for a size of the cooking utensil detected over burner assembly 16. Further, lighting system 42 is powered directly from power supply and source 40 and/or powered by an induced magnetic field generated by burner assembly 16.

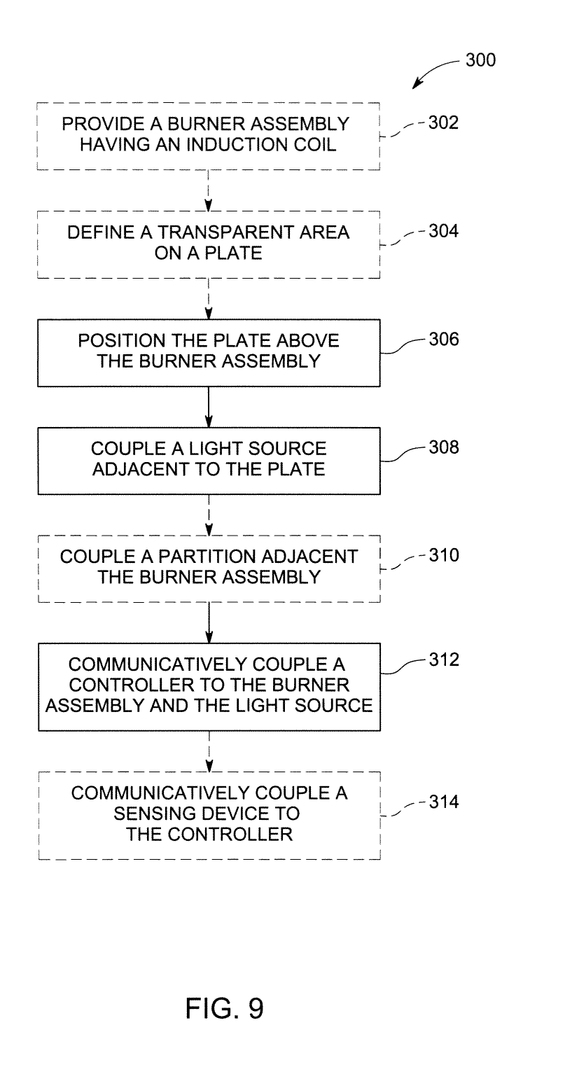

FIG. 9 is a flowchart of an exemplary method 300 for assembling cooktop appliance 10 (shown in FIG. 1). Referring to FIGS. 1-4 and 9, method 300 includes providing 302 burner assembly 16 including induction coil 26. First area 54 is defined 304 on top surface 20 of plate 12. More specifically, to define 304 first area 54, an area surrounding pattern 14 is rendered opaque by applying a coating, etching, cutting, and/or any other suitable technique that enables lighting system 42 to function as described herein. Plate 12 is positioned 306 above burner assembly 16 such that first area 54 is aligned with burner assembly 16. In the exemplary embodiment, first area 54 is positioned above burner assembly 16. At least one light source 46 and/or 48 is coupled 308 adjacent light entry portal 50 of plate 12. Light source 46 and/or 48 is positioned and/or configured to direct light through plate 12 via light entry portal 50.

In a particular embodiment, a plurality of light sources 46 and 48 are coupled 308 adjacent at least one light entry portal 50 of plate 12 and each light source 46 and 48 is configured to emit a different color of light. When cooktop appliance 10 includes a plurality of burner assemblies 16 as shown in FIGS. 4 and 5, at least one light source 46 and/or 48 is coupled 308 adjacent each burner assembly 16. For example, a pair of light sources 46 and 48 is associated with each burner assembly 16 in cooktop appliance 10. Partitions 44 can be coupled 310 between adjacent burner assemblies 16 and prevent the light from passing therethrough. Partitions 44 are especially desirable when burner assemblies are arranged in a grid and/or an array.

In the exemplary embodiment, plate 12 is configured to emit the light from top surface 20 at first area 54. As such, plate 12 and/or first area 54 act as light guides that guide light from light sources 46 and/or 48 through plate 12 to a user of cooktop appliance 10. Controller 24 is communicatively coupled 312 to burner assembly 16 and light source 46 and/or 48. In the exemplary embodiment, controller 24 is configured to activate light source 46 and/or 48 when burner assembly 16 is activated and/or a utensil above burner assembly 16 has been heated, as described above. Further, at least one sensing device 34 is communicatively coupled 314 to controller 24. Controller 24 is configured to control light source 46 and/or 48 to produce at least one of a predetermined color of light and a predetermined pattern of light at burner assembly 16 to indicate a characteristic sensed by sensing device 34.

The embodiments described herein provide a user of an induction cooktop appliance with a visual indication of a state, a status, and/or a mode of the induction cooktop appliance. More specifically, the lighting system provides the user visual indications using color, pattern, intensity, and/or duration of lighting to inform the user about the state, the status, and/or the mode. The lighting system is not only informative, but visually appealing to users. Because the lighting system informs the user about the status of the cooktop appliance, the cooktop appliance described herein is safer for the user, as compared to conventional induction cooktop appliances.

A technical effect of the systems and method described herein includes at least one of: (a) activating at least one light source when a burner assembly is activated; (b) operating at least one light source in a first mode when a burner assembly is operating at a first state and operating the at least one light source in a second mode when the burner assembly is operating at a second state; (c) activating at least one light source to emit a first color of light when a burner assembly is operating at a first state and to emit a second color of light when the burner assembly is operating at a second state; (d) gradually changing a color of light emitted from at least one light source from a first color to a second color; (e) receiving a user input of a color of light to emit from at least one light source; and (f) operating at least one light source in a first mode when a burner assembly is operating at a first state and operating the at least one light source in a second mode when the burner assembly is operating at a second state.

Exemplary embodiments of a lighting system for use with a cooktop appliance and a method for assembling the same are described above in detail. The systems and method are not limited to the specific embodiments described herein, but rather, components of systems and/or steps of the methods may be utilized independently and separately from other components and/or steps described herein.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A lighting system for use with a cooktop appliance, the cooktop appliance comprising a plate and a burner assembly positioned beneath the plate, said lighting system comprising:
at least one light source positioned adjacent a light entry portal of the plate, said at least one light source configured to direct light through the plate via the light entry portal and emit the light from a top surface of the plate adjacent the burner assembly; and
a controller communicatively coupled to the burner assembly and said at least one light source, said controller configured to activate said at least one light source when at least one of the burner assembly is activated and a utensil on the burner assembly is heated.

2. A lighting system in accordance with claim 1, wherein said at least one light source comprises a plurality of light sources adjacent at least one light entry portal of the plate, each light source of said plurality of light sources configured to emit a different color of light.

3. A lighting system in accordance with claim 1, wherein said controller is configured to operate said at least one light source in a first mode when the burner assembly is operating at a first state and to operate said at least one light source in a second mode when the burner assembly is operating at a second state.

4. A lighting system in accordance with claim 1, wherein said controller is configured to operate said at least one light source to emit a first intensity of light when the burner assembly is operating at a first state and to emit a second intensity of light when the burner assembly is operating at a second state.

5. A lighting system in accordance with claim 1, wherein said controller is further configured to activate said at least one light source to emit a first color of light when the burner assembly is operating at a first state and to emit a second color of light when the burner assembly is operating at a second state.

6. A lighting system in accordance with claim 5, wherein said controller is configured to change a color of light emitted from said at least one light source from the first color to the second color.

7. A lighting system in accordance with claim 1, wherein said controller is configured to receive a user input at least one of a color of light, an intensity of light, and a pattern of light to emit from said at least one light source.

8. A cooktop appliance, comprising:
a plate comprising a light entry portal;
a burner assembly positioned beneath said plate, said burner assembly comprising an induction coil; and
a lighting system comprising at least one light source positioned adjacent said light entry portal, said at least one light source configured to direct light through said plate via said light entry portal and emit the light from a top surface of said plate adjacent said burner assembly.

9. A cooktop appliance in accordance with claim 8, further comprising a controller communicatively coupled to said burner assembly and said lighting system, said controller configured to activate said at least one light source when at least one of said burner assembly is activated and a utensil on said burner assembly is heated.

10. A cooktop appliance in accordance with claim 9, further comprising at least one sensing device, said controller configured to control said lighting system to produce at least one of a predetermined color of light and a predetermined pattern of light at said burner assembly to indicate a characteristic sensed by said at least one sensing device.

11. A cooktop appliance in accordance with claim 8, wherein said at least one light source comprises a plurality of light sources that each emit a different color of light.

12. A cooktop appliance in accordance with claim 11, wherein said plate comprises a plurality of light entry portals and each of said plurality of light sources is positioned adjacent a respective light entry portal of said plurality of light entry portals.

13. A cooktop appliance in accordance with claim 8, wherein said plate comprises:
a first area adjacent said burner assembly for directing the light from said top surface of said plate; and
a second area surrounding said first area, said second area preventing the light from being directed through said top surface of said plate.

14. A cooktop appliance in accordance with claim 8, wherein said plate comprises a plurality of first areas surrounded by a second area, said cooktop appliance further comprising:
a plurality of burner assemblies each positioned adjacent a respective area of said plurality of first areas, wherein said at least one light source comprises a plurality of light sources each positioned adjacent a respective burner assembly of said plurality of burner assemblies.

15. A cooktop appliance in accordance with claim 14 further comprising a partition positioned between adjacent burner assemblies of said plurality of burner assemblies, said partitions configured to prevent light from passing therethrough.

16. A method for assembling a cooktop appliance, the cooktop appliance including a burner assembly having an induction coil, said method comprising:
positioning a plate above the burner assembly, the plate including a first area defined on a top surface of the plate, the first area aligned with the burner assembly;
coupling at least one light source adjacent a light entry portal of the plate, the at least one light source configured to direct light through the plate via the light entry portal and emit the light from the top surface of the plate at the first area; and
communicatively coupling a controller to the burner assembly and the at least one light source.

17. A method in accordance with claim 16 further comprising coupling a partition adjacent the burner assembly to prevent the light from being emitted other than at the first area aligned with the burner assembly.

18. A method in accordance with claim 16, wherein positioning a plate above the burner assembly further comprises positioning a plate having a second area surrounding the first area aligned with the burner assembly, the second area preventing light from being emitting from the top surface of the plate.

19. A method in accordance with claim 16, further comprising communicatively coupling at least one sensing device to the controller, the controller configured to control the at least one light source to produce at least one of a predetermined color of light and a predetermined pattern of light at the burner assembly to indicate a characteristic sensed by the at least one sensing device.

20. A method in accordance with claim 16, wherein coupling at least one light source adjacent a light entry portal of the plate comprises coupling a plurality of light sources adjacent at least one light entry portal of the plate, each light source of the plurality of light sources configured to emit a different color of light.
